(19) United States
(12) Patent Application Publication
(10) Pub. No.: US 2025/0125200 A1
(43) Pub. Date: Apr. 17, 2025

(54) THREE-DIMENSIONAL (3D) PACKAGES AND METHODS FOR 3D PACKAGING

(71) Applicant: Murata Manufacturing Co., Ltd., Kyoto (JP)

(72) Inventor: Stephen John ALLEN, San Diego, CA (US)

(21) Appl. No.: 18/991,178

(22) Filed: Dec. 20, 2024

Related U.S. Application Data
(63) Continuation of application No. PCT/US2023/068778, filed on Jun. 21, 2023.
(60) Provisional application No. 63/366,773, filed on Jun. 21, 2022.

(51) Int. Cl. H01L 23/04; H01L 23/31; H01L 23/538; H01L 25/18

(52) U.S. Cl. CPC H01L 23/041; H01L 23/5385; H01L 25/18; H01L 23/3107

(57) ABSTRACT

A three-dimensional (3D) package includes one or more frames, circuit assemblies, and an encapsulating material to encapsulate at least a part of the one or more frames and the circuit assemblies. The one or more frames each include one or more supporting portions and conductive connecting portions extending from the one or more supporting portions and defining assembly mounting spaces therebetween. Circuit assemblies are each mounted in one assembly mounting space and electrically attached to corresponding one or more of the first and second conductive connecting portions.

### CROSS-REFERENCE TO RELATED APPLICATIONS

This application is a continuation of International Patent Application No. PCT/US2023/068778 filed Jun. 21, 2023 and entitled “THREE-DIMENSIONAL (3D) PACKAGES AND METHODS FOR 3D PACKAGING,” which claims priority to and the benefit of U.S. Provisional Patent Application No. 63/366,773 filed Jun. 21, 2022 and entitled “THREE-DIMENSIONAL (3D) PACKAGES AND METHODS FOR 3D PACKAGING,” all of which are incorporated herein by reference in their entirety.

### TECHNICAL FIELD

The present disclosure generally relates to semiconductor and power electronics manufacturing. More particularly, the present disclosure relates to three-dimensional (3D) packaging for power electronic devices.

### BACKGROUND

Semiconductor packages are widely used for protecting an integrated circuit (IC) chip and providing an electrical interface to external circuitry. With increasing demand for smaller device sizes and higher power densities, packages for power modules are designed to be more compact with increased circuit density. In 3D semiconductor packaging for power devices, stacking dies and associated passive components often generate significant heat and result in thermal hotspots due to high-power devices within the packages. With 3D or stacked substrate packages, one or more dies may be covered by other dies and thus not exposed to the surface, preventing these dies from interfacing directly with a heat sink for heat dissipation.

Accordingly, designing a semiconductor package with sufficient heat dissipation properties to remove heat dissipated within each power device has become a challenge in the field. In addition, 3D semiconductor packaging also causes routing challenges and difficulties in providing efficient connections between devices arranged vertically in the package. Thus, there is a need to simplify routing complexity for 3D semiconductor packaging.

### SUMMARY

Embodiments of the present disclosure provide a 3D package. The 3D package includes one or more frames, circuit assemblies, and an encapsulating material to encapsulate at least a part of the one or more frames and the circuit assemblies. The one or more frames each include one or more supporting portions and conductive connecting portions extending from the one or more supporting portions and defining assembly mounting spaces therebetween. The circuit assemblies are each mounted in one of the assembly mounting spaces and electrically attached to corresponding one or more of the conductive connecting portions.

Embodiments of the present disclosure provide a frame structure for stacking circuit assemblies. The frame structure includes two supporting portions extending substantially along a first direction, first conductive connecting portions extending substantially along a second direction from one of the two supporting portions, and second conductive connecting portions extending substantially along the second direction from another one of the two supporting portions. The first conductive connecting portions and the second conductive connecting portions define mounting spaces therebetween for mounting the circuit assemblies. In a first connecting portion pair extending from first ends of the two supporting portions, a corresponding one of the first conductive connecting portions and a corresponding one of the second conductive connecting portions are formed in response to a sacrificial process removing a first connector portion protruding from the frame structure at a first side. The first conductive connecting portions and the second conductive connecting portions are disposed for electrically attaching to corresponding conductive pads of the circuit assemblies.

Embodiments of the present disclosure provide a method for 3D packaging. The method includes: mounting circuit assemblies within assembly mounting spaces defined by a first frame and a second frame aligned with the first frame, the first frame comprising one or more first supporting portions and first conductive connecting portions extending from the one or more first supporting portions and defining first mounting spaces, the second frame comprising one or more second supporting portions and second conductive connecting portions extending from the one or more second supporting portions and defining second mounting spaces, the first mounting spaces aligned with the second mounting spaces to form the assembly mounting spaces; and applying an over-molding to obtain a molded package encapsulating the circuit assemblies, the first frame, and the second frame.

Embodiments of the present disclosure provide three-dimensional (3D) package. The 3D package includes frames aligned with each other and circuit assemblies. Any of the frames includes two supporting portions extending substantially along a first direction and conductive connecting portions defining mounting spaces, corresponding mounting spaces of the frames are aligned with each other to define an assembly mounting space. The circuit assemblies are each mounted in one of the assembly mounting spaces and each electrically attached to corresponding conductive connecting portions extending along a second direction substantially perpendicular to conductive terminals of the 3D package.

Embodiments of the present disclosure provide a non-transitory computer-readable storage medium storing a set of instructions that are executable by one or more processors of a device to cause the device to perform a method for designing a frame structure for stacking circuit assemblies. The method includes: providing two supporting portions extending substantially along a first direction; providing first conductive connecting portions extending substantially along a second direction from one of the two supporting portions; providing of second conductive connecting portions extending substantially along the second direction from another one of the two supporting portions, the first conductive connecting portions and the second conductive connecting portions defining mounting spaces therebetween for mounting the circuit assemblies; and providing a first connector portion protruding from the frame structure at a first side, in which the first connector portion is associated with a corresponding one of the first conductive connecting portions and a corresponding one of the second conductive connecting portions in a first connecting portion pair extending from first ends of the two supporting portions, and to be removed during a sacrificial process. The first conductive connecting portions and the second conductive connecting portions are disposed for electrically attaching to corresponding conductive pads of the circuit assemblies.

Embodiments of the present disclosure provide a frame structure for stacking circuit assemblies. The frame structure includes one or more first portions configured to provide one or more electrical terminals for transmitting, through a first path, electrical power for a power supply circuit formed by the circuit assemblies, and one or more second portions configured to provide one or more heat dissipation surfaces to transfer heat from the circuit assemblies through a second path different from the first path.

Additional features and advantages of the disclosed embodiments will be set forth in part in the following description, and in part will be apparent from the description, or may be learned by practice of the embodiments. The features and advantages of the disclosed embodiments may be realized and attained by the elements and combinations set forth in the claims.

### BRIEF DESCRIPTION OF THE DRAWINGS

Embodiments and various aspects of the present disclosure are illustrated in the following detailed description and the accompanying figures. It is noted that, in accordance with standard practice in the industry, various features are not drawn to scale. In fact, the dimensions of the various features may be arbitrarily increased or reduced for clarity of discussion.

FIG. 1A and FIG. 1B are respective top and bottom views of an exemplary semiconductor package, in accordance with some embodiments of the present disclosures.

FIG. 2A and FIG. 2B are respective top and bottom views of an exemplary power circuit assembly to be molded in the semiconductor package 100, in accordance with some embodiments of the present disclosures.

FIG. 3A and FIG. 3B are two perspective views illustrating multiple power circuit assemblies stacked in the semiconductor package, in accordance with some embodiments of the present disclosures.

FIG. 3C is a perspective view illustrating a heatsink attaching to frames in the semiconductor package of FIG. 3A and 3B, in accordance with some embodiments of the present disclosures.

FIG. 4 is a flowchart of a method for three-dimensional (3D) packaging, in accordance with some embodiments of the present disclosure.

FIG. 5A is a diagram illustrating exemplary frame structures for stacking power circuit assemblies, in accordance with some embodiments of the present disclosure.

FIG. 5B is a diagram illustrating another exemplary frame structure for stacking power circuit assemblies, in accordance with some embodiments of the present disclosure.

FIG. 6 and FIG. 7 are diagrams illustrating power circuit assemblies accommodated and stacked vertically in frame structures, in accordance with some embodiments of the present disclosure.

FIG. 8 and FIG. 9 are respective top and bottom views of the frame structures shown in FIG. 5A after the grinding process, in accordance with some embodiments of the present disclosures.

FIG. 10 is a diagram illustrating an exemplary assembly with an additional frame structure arranged between the frame structures shown in FIG. 5A, in accordance with some embodiments of the present disclosure.

FIG. 11 is a diagram illustrating an exemplary assembly, demonstrating a scaled-up example based on FIG. 10, in accordance with some embodiments of the present disclosure.

FIG. 12A and FIG. 12B are respective top and bottom views of another exemplary power circuit assembly, in accordance with some embodiments of the present disclosures.

FIG. 13 is a diagram illustrating exemplary frame structures for stacking multiple power circuit assemblies of FIG. 12A and FIG. 12B, in accordance with some embodiments of the present disclosure.

FIG. 14 is a diagram illustrating power circuit assemblies accommodated and stacked in frame structures, in accordance with some embodiments of the present disclosure.

FIG. 15A and FIG. 15B are respective top and bottom views of an exemplary semiconductor package, in accordance with some embodiments of the present disclosures.

### DETAILED DESCRIPTION

The following disclosure provides many different exemplary embodiments, or examples, for implementing different features of the provided subject matter. Specific simplified examples of components and arrangements are described below to explain the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this document, the term “coupled” may also be termed as “electrically coupled”, and the term “connected” may be termed as “electrically connected”. “Coupled” and “connected” may also be used to indicate that two or more elements cooperate or interact with each other.

Various embodiments of the present disclosure will be described with respect to embodiments in a specific context, namely a charge pump circuit. As used in this disclosure, the term “charge pump” refers to a switched-capacitor network configured to convert an input voltage to an output voltage. Examples of such charge pumps include cascade multiplier, Dickson, ladder, series-parallel, Fibonacci, and Doubler switched-capacitor networks, all of which may be configured as a multi-phase or a single-phase network. The concepts in the disclosure may also apply, however, to other types of power IC devices using 2.5D/3D packaging technologies.

In the context of the present disclosure, power converting circuits which convert a higher input voltage power source to a lower output voltage level are commonly known as step-down or buck converters, because the converter is “bucking” the input voltage. Power converting circuits which convert a lower input voltage power source to a higher output voltage level are commonly known as step-up or boost converters, because the converter is “boosting” the input voltage. In addition, some power converters, commonly known as “buck-boost converters,” may be configured to convert the input voltage power source to the output voltage with a wide range, in which the output voltage may be either higher than or lower than the input voltage. In various embodiments, a power converter may be bidirectional, being either a step-up or a step-down converter depending on how a power source is connected to the converter. In some embodiments, an AC-DC power converter can be built up from a DC-DC power converter by, for example, first rectifying an AC input voltage to a DC voltage and then applying the DC voltage to a DC-DC power converter.

Integrated circuits (ICs) and the semiconductor packages in accordance with the present disclosure may be used alone or in combination with other components, circuits, devices, and packages. For example, the packages may be combined with other components, such as on a printed circuit board, to form part of a power module, a power converter device, a power supply system, or an end product such as a cellular telephone, laptop computer, or electronic tablet, or to form a higher-level module or system which may be used in a wide variety of products, such as energy management systems for computing devices, industrial devices, medical devices, large-scale data centers, vehicle electrical systems in automotive applications, etc.

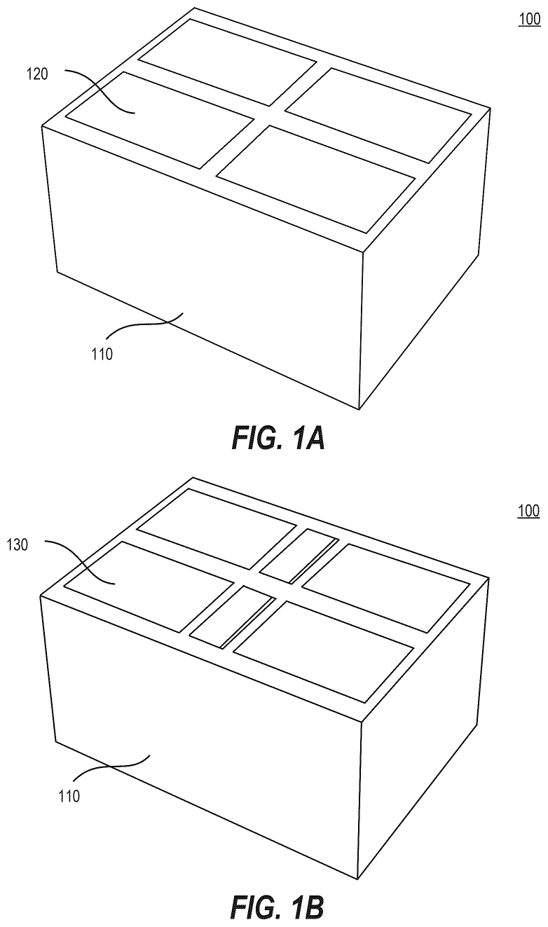

FIG. 1A and FIG. 1B are respective top and bottom views of an exemplary semiconductor package 100, in accordance with some embodiments of the present disclosures. The semiconductor package 100 may be a three-dimensional (3D) package with a molded body 110 encapsulating, among other things, multiple power circuit assemblies. For example, the power circuit assemblies may be vertically stacked Power Supply in Packages (PSiPs) implementing power converting circuits, such as charge pump circuits. Based on the charge-pump, switched-capacitor architecture performing the power conversion, the semiconductor package 100 can be used in various power supply applications. In some embodiments, the mold material forming the molded body 110 is thermally conductive, which may facilitate heat transfer and avoid damage or performance degradation due to heat accumulation in the semiconductor package 100.

As shown in FIG. 1A and FIG. 1B, the semiconductor package 100 may provide multiple top-side terminals 120 at a top surface of the semiconductor package 100 and multiple bottom-side terminals 130 at a bottom surface of the semiconductor package 100. For example, in the semiconductor package 100 of FIG. 1A and FIG. 1B, four top-side terminals 120 are disposed in an example alignment and six bottom-side terminals 130 are disposed in an example alignment. In other words, the number of the top-side terminals 120 may be different from the number of the bottom-side terminals 130. In addition, as shown in FIG. 1B, in some embodiments, bottom-side terminals 130 may include terminals with different sizes. In some embodiments, the top-side terminals 120 are configured to provide heatsinking functionality for components and devices within the semiconductor package 100. The bottom-side terminals 130 are configured to provide input terminal(s), output terminals, and/or ground terminal(s) for the power supply circuit.

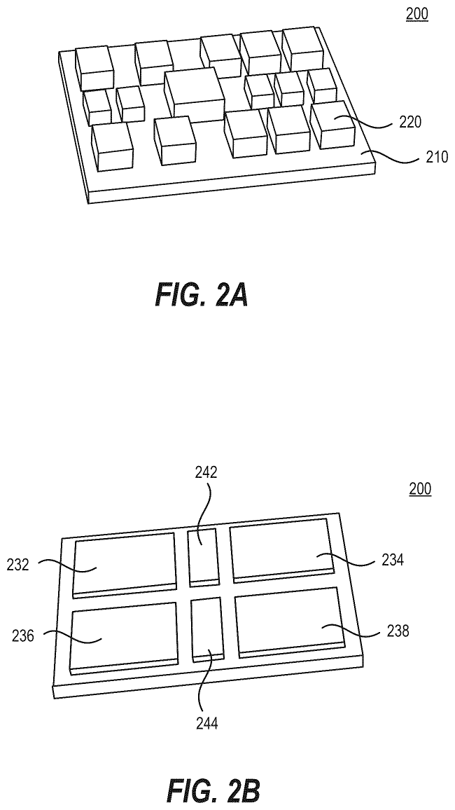

FIG. 2A and FIG. 2B are respective top and bottom views of an exemplary power circuit assembly 200 to be molded in the semiconductor package 100, in accordance with some embodiments of the present disclosures. As shown in FIG. 2A, in some embodiments, the power circuit assembly 200 includes a substrate 210, with one or more passive components 220 mounted on a first side (e.g., a top side) of the substrate 210. In an embedded die-in-substrate design, the semiconductor die is embedded in the substrate 210 and attached to a lead-frame to minimize the size and maximize the thermal transfer efficiency. In some embodiments, one power circuit assembly 200 may deliver up to approximately 100W output power, but the present disclosure is not limited thereto. In some embodiments, the height of the substrate 210 may be varied from approximately 1.0 mm to approximately 2.0 mm, but the present disclosure is not limited thereto. In some embodiments, the power circuit assembly 200 may be a full power converter. In some other embodiments, the power circuit assembly 200 may include one or more field-effect transistors (FETs). In some other embodiments, the power circuit assembly 200 may be one or more portions of a power converter.

The passive components 220 may include inductors, capacitors, and/or resistors, for a charge pump circuit or other types of power converting circuits. As shown in FIG. 2B, in some embodiments, conductive pads 232, 234, 236, 238, 242 and 244 are mounted on a second side (e.g., a bottom side) opposite the first side. Each of the conductive pads 232, 234, 236, 238, 242 and 244 may be electrically coupled to one or more corresponding passive components 220 mounted on the first side via conductive features, such as vias or conductive lines, located on or within the substrate 210.

Accordingly, conductive pads 232, 234, 236, 238, 242 and 244 can be configured to provide electrical connection paths to other power circuit assemblies in the same package. In the embodiment shown in FIG. 2B, conductive pads 232, 234, 236, 238, 242 and 244 include conductive pads with different sizes in an example alignment, but the present disclosure is not limited thereto. In various embodiments, the power circuit assembly 200 may accommodate any number of conductive pads formed or mounted on the bottom side, based on the layout design consideration.

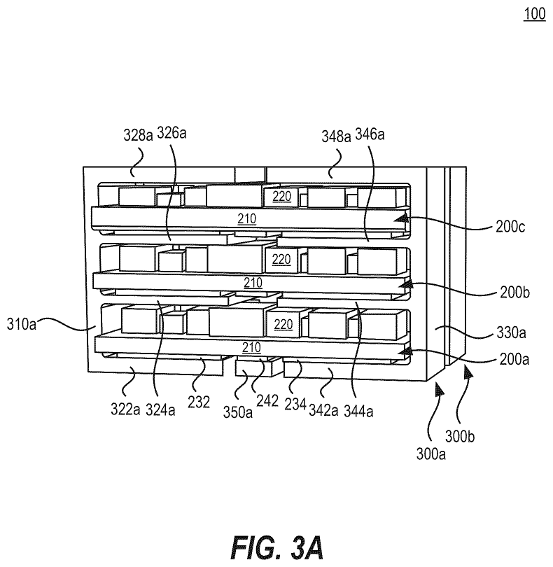

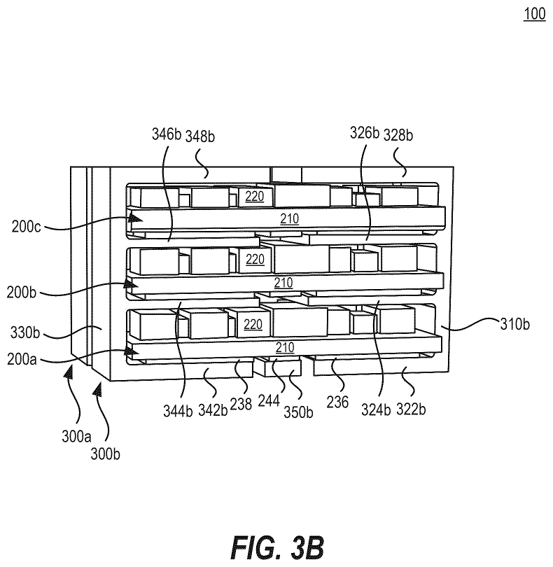

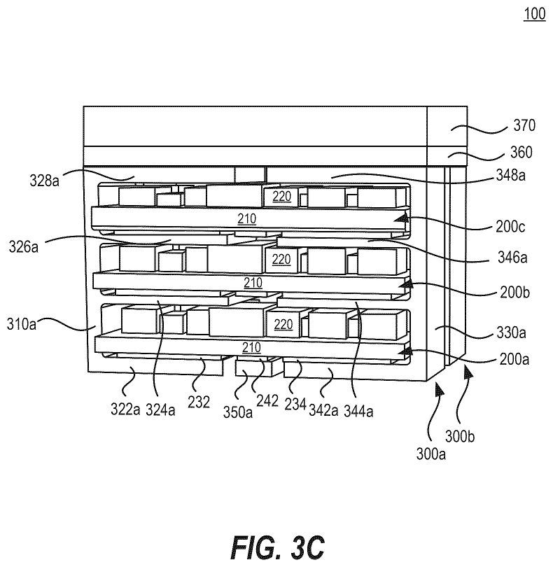

FIG. 3A and FIG. 3B are two perspective views illustrating multiple power circuit assemblies 200a, 200b, and 200c stacked in the semiconductor package 100, in accordance with some embodiments of the present disclosures. For better understanding of the present disclosure, the mold material encapsulating power circuit assemblies 200a, 200b, and 200c is not shown in FIG. 3A and FIG. 3B.

As shown in FIG. 3A, the semiconductor package 100 includes frames 300a and 300b for stacking power circuit assemblies 200a, 200b, and 200c vertically within the semiconductor package 100. In some embodiments, the frames 300a and 300b may have identical shapes and features and are aligned to each other. In other embodiments, the frames 300a and 300b may have complementary shapes and features that are aligned to each other. In different embodiments, the frames 300a and 300b may be extruded parts, machined parts, such as computer numerically-controlled (CNC) machined parts, 3D printed parts, or parts fabricated using any other suitable process selected according to, for example, the dimension and/or the structure of the parts.

In some embodiments, the frames 300a and 300b are thermally and electrically conductive. For example, the frames 300a and 300b may be extrusion structures, such as copper extrusions, which provide structural rigidity and thermal conductivity for the stacked power circuit assemblies with a low cost. In addition, copper frames also provide desired electrical conductivity to minimize power loss. In some other embodiments, the frames 300a and 300b may also be CNC machined parts or 3D printed parts formed by 3D printing using powdered copper, e.g., if more elaborate inter-connection designs for the frames 300a and 300b is desired. In addition, in some embodiments, the 3D printing technology can be applied in a validation process for validating the extrusion concept or design under development without additional tooling costs.

The frame 300a includes supporting portions 310a, 330a extending along a first direction (e.g., substantially vertically), conductive connecting portions 322a, 324a, 326a, 328a extending along a second direction (e.g., substantially horizontally) from the supporting portion 310, and conductive connecting portions 342a, 344a, 346a, 348a extending along the second direction (e.g., substantially horizontally) from the supporting portion 330a, and a conductive connecting portion 350a between conductive connecting portions 322a and 342a. Accordingly, conductive connecting portions 322a-328a and 342a-348a in the frame 300a define first mounting spaces therebetween for accommodating and mounting power circuit assemblies 200a, 200b, and 200c. Particularly, in FIG. 3A, the conductive connecting portions 322a-328a and 342a-348a extend substantially horizontally in pairs toward each other from the two supporting portions 310a and 330a. Adjacent pairs of the conductive connecting portions 322a-328a and 342a-348a define the first mounting spaces therebetween.

In some embodiments, conductive connecting portions 322a, 324a, 326a, and 328a serve different purposes, and corresponding conductive connecting portions 342a, 344a, 346a, and 348a on the other side may respectively provide similar functionality of the conductive connecting portions 322a, 324a, 326a, and 328a. For example, the conductive connecting portions 322a and 342a are configured to connect to a printed circuit board (PCB) substrate. Both top and bottom of the conductive connecting portions 322a, 342a require a solderable material. On the other hand, for the conductive connecting portions 324a, 326a and the conductive connecting portions 344a, 346a, only one side (e.g., the top side) requires a solderable material. The conductive connecting portions 328a, 348a does not require solderable material. In some embodiments, the conductive connecting portions 328a, 348a may provide an electrical insulator, which is thermally conductive, for the attachment of a heatsink. In various embodiments, the frames 300a and 300b may have different amounts of supporting portions that extend along the first direction.

Similarly, as shown in FIG. 3B, the frame 300b aligned with the frame 300a also includes supporting portions 310b, 330b extending substantially vertically, conductive connecting portions 322b, 324b, 326b, 328b extending substantially horizontally from the supporting portion 310b, and conductive connecting portions 342b, 344b, 346b, 348b extending substantially horizontally from the supporting portion 330b, and a conductive connecting portion 350b between conductive connecting portions 322b and 342b. Conductive connecting portions 322b-328b and 342b-348b in the frame 300b define second mounting spaces therebetween for accommodating and mounting power circuit assemblies 200a, 200b, and 200c, with adjacent pairs of the conductive connecting portions 322b-328b and 342b-348b defining the second mounting spaces therebetween. Thus, each of the first mounting spaces is aligned with a corresponding one of the second mounting spaces to define an assembly mounting space for one power circuit assembly.

It will be appreciated that the number of conductive connecting portions, the number of assembly mounting spaces, and/or the number of power circuit assemblies in a single semiconductor package 100 may be modified according to practical needs. For example, the semiconductor package 100 is scalable vertically, with two, three, four, or more power circuit assemblies installed vertically. The embodiment of FIG. 3A is an example and not meant to limit the present disclosure.

In the embodiment of FIG. 3A and FIG. 3B, power circuit assemblies 200a, 200b, and 200c are each mounted in one of the assembly mounting spaces and electrically attached (e.g., soldered) to corresponding one or more of the conductive connecting portions 322a-328a, 342a-348a of the frame 300a, and corresponding one or more of the conductive connecting portions 322b-328b, 342b-348b of the frame 300b. In some embodiments, the power circuit assembly 200a in a bottom layer may be configured to interface with power circuit assemblies 200b and 200c in the stack by AC coupled communication. Accordingly, the frames 300a and 300b provide electrical connections among devices in the stacked power circuit assemblies 200a-200c, and thus facilitate the vertical connection in the semiconductor package 100. In some embodiments, frames 300a and 300b are copper frames, in which the thickness (e.g., approximately 300 um-1 mm) of copper for each intermediate interconnect can be sized to a desired thickness to optimize the thermal performance without the risk of warpage.

As shown in the figures, the power circuit assembly 200a in the bottom layer is electrically attached to conductive connecting portions 322a, 342a, and 350a of the frame 300a respectively via conductive pads 232, 234 and 242, and is electrically attached to conductive connecting portions 322b, 342b, and 350b of the frame 300b respectively via conductive pads 236, 238 and 244. Similarly, the power circuit assemblies 200b and 200c in a middle layer and a top layer are respectively electrically attached to conductive connecting portions 324a, 344a and conductive connecting portions 326a, 346a of the frame 300a, and respectively electrically attached to conductive connecting portions 324b, 344b and conductive connecting portions 326b, 346b of the frame 300b, via corresponding conductive pads. By this arrangement, each of the power circuit assemblies 200a, 200b, and 200c can be located into two frames 300a and 300b (e.g., extrusion frames) with interconnects between conductive pads and the copper lead frame underneath.

In some applications, after the power circuit assemblies 200a-200c are electrically attached to the frames 300a and 300b, the molding process is performed to provide molding material for encapsulating at least a part of the frame 300a, the frame 300b, and the power circuit assemblies 200a-200c, to obtain the semiconductor package 100 for power conversion applications shown in FIG. 1A and FIG. 1B after a post molding process (e.g., a grinding process).

For example, after the grinding process, a top connecting portion pair (e.g., conductive connecting portions 328a and 348a) of the frame 300a and a top connecting portion pair (e.g., conductive connecting portions 328b and 348b) of the frame 300b are exposed from the mold material to form conductive top-side terminals 120 on the top side of the semiconductor package 100. Similarly, after the grinding process, a bottom connecting portion pair (e.g., conductive connecting portions 322a and 342a) of the frame 300a and a bottom connecting portion pair (e.g., conductive connecting portions 322b and 342b) of the frame 300b are exposed from the mold material to form conductive bottom-side terminals 130 on the bottom side of the semiconductor package 100. In addition, conductive connecting portions 350a and conductive connecting portions 350b are also exposed from the mold material to form conductive terminals 130.

As previously discussed, the top-side terminals may provide heatsinking functionality for components and devices within the semiconductor package 100. By using thermally conductive frames 300a and 300b (e.g., copper frames) and thermally conductive molding material, the heat dissipated within the power circuit assemblies 200a-200c can be removed efficiently. In some embodiments, the frame 300a, the frame 300b, or both may include one or more heatsink fins arranged in an array and extending from the top portion of the frame 300a or the frame 300b to further facilitate the thermal dissipation. For example, heatsink fins may be elongated, substantially flat members arranged substantially parallel with one another and configured to increase the heat transfer area.

FIG. 3C is a perspective view illustrating a heatsink attaching to frames 300a and 300b, in accordance with some embodiments of the present disclosures. In the embodiments of FIG. 3C, the semiconductor package 100 further includes an electrical insulator layer 360 and a heatsink 370 over the frames 300a and 300b. As shown in FIG. 3C, the electrical insulator layer 360 is attached above to the top connecting portion pair, e.g., conductive connecting portions 328a and 348a, of the frame 300a. Similarly, the electrical insulator layer 360 is also attached above to the top connecting portion pair of the frame 300b. The electrical insulator layer 360, which is electrically insulated and thermally conductive, can conduct heat away from the frames 300a and 300b. For example, the electrical insulator layer 360 may be formed of thermally conductive ceramics or resin, or other material with the same or similar electrical and thermal properties.

The heatsink 370 is disposed on top of and attached to the electrical insulator layer 360. For example, the heatsink 370 may include a sheet of conductive metal, such as aluminum or copper, for conducting heat away from the electrical insulator layer 360. In some embodiments, different types of heat transfer devices, such as heat straps, heat pipes, heat spreaders, etc., may also be used in a thermal management system to facilitate heat transfer and remove the heat generated in the semiconductor package 100.

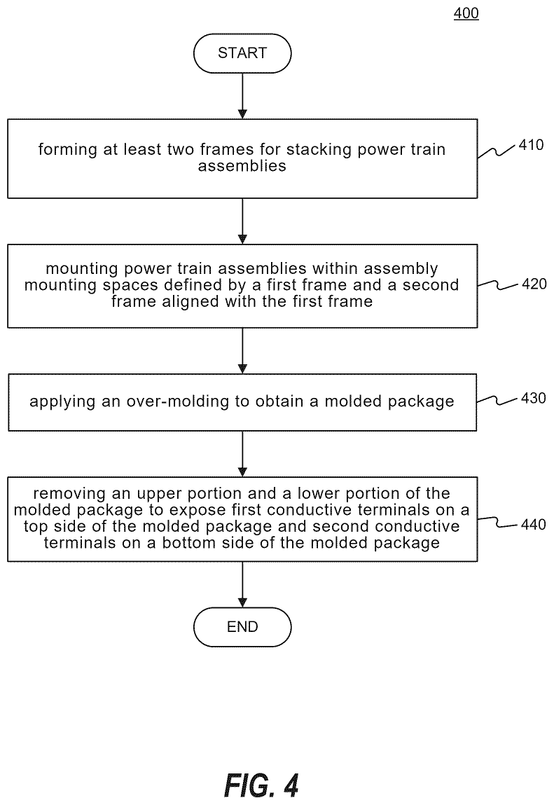

FIG. 4 is a flowchart of a method 400 for three-dimensional (3D) packaging, in accordance with some embodiments of the present disclosure. It is understood that additional operations may be performed before, during, and/or after the method 400 depicted in FIG. 4, and that some other processes may only be briefly described herein. The method 400 can be performed to manufacture a 3D package for charge pump devices with increased power density, e.g., the semiconductor package 100 illustrated in FIG. 1A and FIG. 1B, but the present disclosure is not limited thereto. The method 400 includes operations 410, 420, 430, and 440.

In operation 410, at least two frames for accommodating and stacking power circuit assemblies are formed. In some embodiments, at least one of the frames can be formed by an extrusion process or a CNC-machining process. In some other embodiments, at least one of the frames can be formed by 3D printing. The frames may be thermally and electrically conductive.

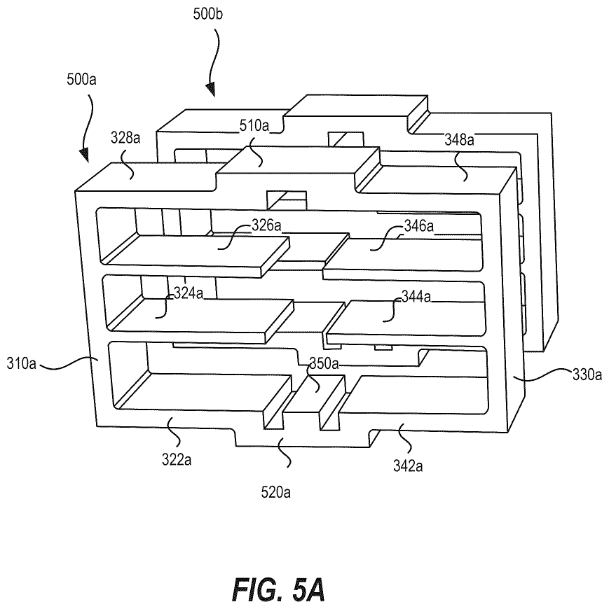

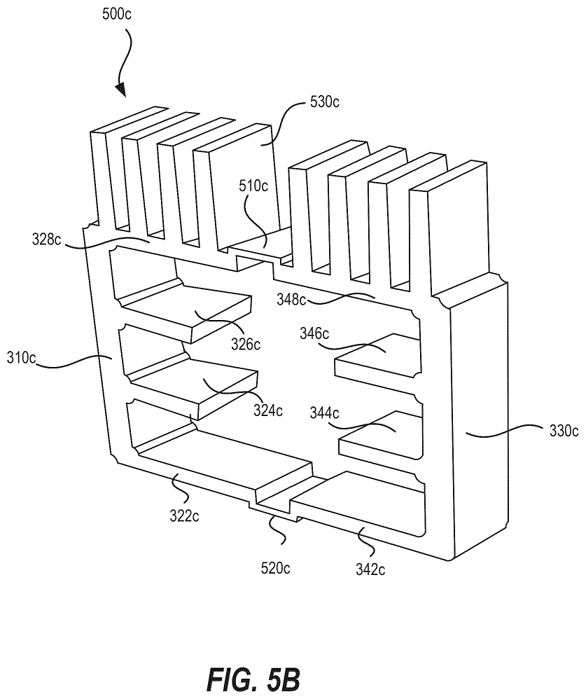

FIG. 5A is a diagram illustrating exemplary frame structures 500a and 500b for stacking power circuit assemblies, in accordance with some embodiments of the present disclosure. Compared to frames 300a and 300b in the final product after the over-molding and top/bottom side grinding process, frame structures 500a and 500b in FIG. 5A include sacrificial connector portions, but the present disclosure is not limited thereto. In some other embodiments, frame structures without sacrificial elements can also be used for stacking power circuit assemblies.

In the frame structure 500a, conductive connecting portions 322a, 324a, 326a, and 328a extending substantially horizontally from one supporting portion 310a, and conductive connecting portions 342a, 344a, 346a, and 348a extending substantially horizontally from another supporting portion 330a form connecting portion pairs, defining mounting spaces therebetween for mounting the power circuit assemblies. Particularly, in some embodiments, corresponding ones of the conductive connecting portions 322a, 324a, 326a, and 328a and the conductive connecting portions 342a, 344a, 346a, and 348a are horizontally aligned and extend in pairs toward each other.

A conductive connecting portion 350a is disposed between the conductive connecting portion 322a and the conductive connecting portion 342a of the bottom connecting portion pair. It is noted that, in some other embodiments, the frame structure 500a may include two or more conductive connecting portions 350a between the conductive connecting portions 322a and 342a. The frame structure 500a in FIG. 5A is an example and not meant to limit the present disclosure. The conductive connecting portions 322a-328a, 342a-348a, and 350 are disposed for soldering to corresponding conductive pads of the power circuit assemblies.

The frame structure 500a further includes sacrificial connector portions 510a and 520a. Particularly, the sacrificial connector portion 510a protrudes from the frame structure 500a at a first side (e.g., the top side) to connect a corresponding conductive connecting portion 328a and a corresponding conductive connecting portion 348a of a top connecting portion pair extending from top ends of the two supporting portions 310a and 330a.

The sacrificial connector portion 520a protrudes from the frame structure 500a at a second side (e.g., a bottom side) opposite the first side to connect a corresponding conductive connecting portion 322a and a corresponding conductive connecting portion 342a of a bottom connecting portion pair extending from bottom ends of the two supporting portions 310a and 330a. In addition, the conductive connecting portion 350a is also connected to the sacrificial connector portion 520a. In some embodiments, the features of the frame structure 500b may be identical or similar to the features of the frame structure 500a, and thus are not repeated herein for the sake of brevity.

FIG. 5B is a diagram illustrating another exemplary frame structure 500c for stacking power circuit assemblies, in accordance with some embodiments of the present disclosure. As mentioned above, the frame 300a, the frame 300b, or both in the final product may include one or more heatsink fins for the thermal dissipation. The frames 300a and 300b with heatsink fins can be formed by applying the frame structure 500c, in which heatsink fins 530c are arranged substantially parallel with one another and extending vertically from top portions (e.g., conductive connecting portions 328c and 348c) of the frame structure 500c to increase the heat transfer area. It is noted that the number, length, thickness, and/or shape of the heatsink fins 530c, or the distance between two adjacent heatsink fins 530c, can be modified according to practical needs, and the example shown in FIG. 5B is not meant to limit the present disclosure. Other features of the frame structure 500c, including conductive connecting portions 322c, 324c, 326c, and 328c extending substantially horizontally from one supporting portion 310c, conductive connecting portions 342c, 344c, 346c, and 348c extending substantially horizontally from another supporting portion 330c, and sacrificial connector portions 510c and 520c, are the same or similar to those of the frame structures 500a and 500b discussed in FIG. 5A, and thus are not repeated herein for the sake of brevity.

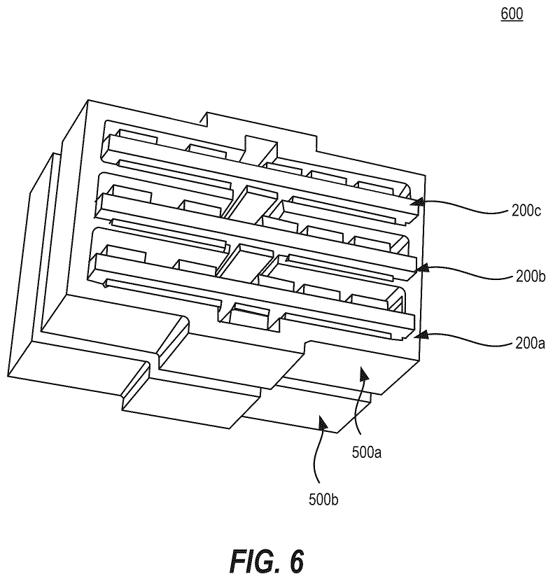

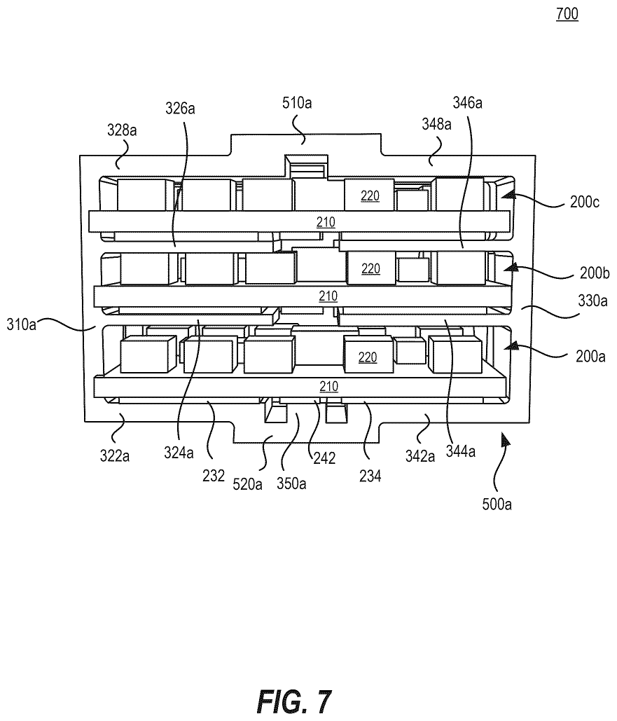

Referring again to FIG. 4, next, in operation 420, the power circuit assemblies are mounted within assembly mounting spaces defined by a first frame and a second frame aligned with the first frame. For example, in the step 420, the power circuit assemblies may be soldered to the first frame and the second frame. Details of the operation 420 will be discussed in association with FIG. 6 and FIG. 7, which are diagrams illustrating power circuit assemblies 200a, 200b, and 200c accommodated and stacked vertically in frame structures 500a and 500b, in accordance with some embodiments of the present disclosure.

As shown in FIG. 6, each of the power circuit assemblies 200a, 200b, and 200c can be inserted into a corresponding assembly mounting space, in which the mounting spaces of the frame structure 500a are aligned with the mounting spaces of the frame structure 500b. Then, the assembly shown in FIG. 6 can be passed through an air flow soldering process line to attach the power circuit assemblies 200a, 200b, and 200c to the two frame structures 500a, 500b by soldering the power circuit assemblies 200a, 200b, and 200c to the frame structures 500a, 500b.

FIG. 7 shows a front view of the power circuit assemblies 200a, 200b, and 200c in the assembly mounting spaces. As shown in the front view of FIG. 7, conductive pads 232, 234, and 242 of each of the power circuit assemblies 200a, 200b, and 200c can be electrically attached respectively to corresponding one or more conductive connecting portions of the frame structure 500a. Similarly, while not shown in FIG. 7, at the opposing side, conductive pads 236, 238, and 244 can be electrically attached respectively to corresponding one or more conductive connecting portions of the frame structure 500b. Accordingly, power circuit assemblies 200a, 200b, and 200c can be mounted within assembly mounting spaces defined by the frame structure 500a and the frame structure 500b aligned with the frame structure 500a.

Referring again to FIG. 4, next, in operation 430, an over-molding is applied to obtain a molded package encapsulating the power circuit assemblies 200a, 200b, and 200c, and the frame structures 500a and 500b. For example, a transfer molding with a thermally conductive material can be applied to fill cavities within the frame structure 500a and the frame structure 500b. In various embodiments, other molding process methods may also be applied to obtain the molded package.

Next, in operation 440, an upper portion and a lower portion of the molded package are removed to expose first conductive terminals on a top side of the molded package and second conductive terminals on a bottom side of the molded package. Particularly, in operation 440, a grinding process can be applied to finish the top surface and the bottom surface of the molded package. As discussed above, frame structures with or without sacrificial elements may both be used for stacking the power circuit assemblies and molded to obtain the molded package. In some embodiments, for the molded package including frame structures with sacrificial elements, when finishing the molded package to expose terminals on the top side and the bottom side, sacrificial connector portion(s) (e.g., sacrificial connector portions 510a and 520a in FIG. 5A) protruding from the frame structure 500a or 500b are also removed by the grinding process grinding the molded package.

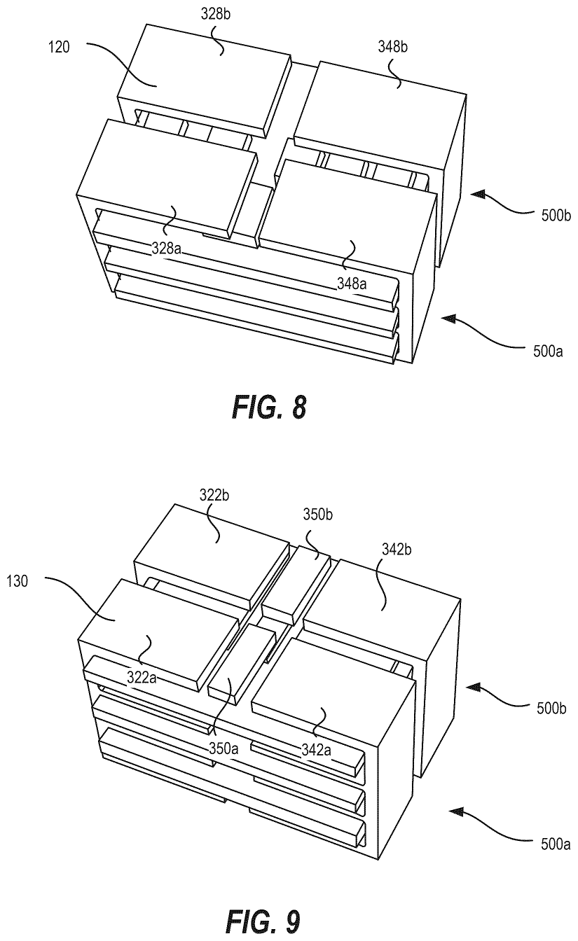

FIG. 8 and FIG. 9 are respective top and bottom views of the frame structures 500a and 500b after the grinding process, in accordance with some embodiments of the present disclosures. For clarity and simplicity purposes, the molded body of the molded package is not shown in FIG. 8 and FIG. 9. As shown in FIG. 8 and FIG. 9, after the grinding process, the top connecting portion pair (e.g., conductive connecting portions 328a and 348a) of the frame structure 500a and the top connecting portion pair (e.g., conductive connecting portions 328b and 348b) of the frame structure 500b are exposed from the mold material to form four conductive terminals (e.g., top-side terminals 120 in FIG. 1A) on the top side of the 3D package. Similarly, the bottom connecting portion pair (e.g., conductive connecting portions 322a and 342a) of the frame structure 500a and the conductive connecting portion 350a therebetween, and the bottom connecting portion pair (e.g., conductive connecting portions 322b and 342b) of the frame structure 500b and the conductive connecting portion 350b therebetween, are also exposed from the mold material to form six conductive terminals (e.g., bottom-side terminals 130 in FIG. 1B) on the bottom side of the 3D package. That is, in the present embodiment, the frame structures 500a and 500b may each include one or more first portions (e.g., conductive connecting portions 322a, 342a, and conductive connecting portions 322b and 342b) on one side, and one or more second portions (e.g., conductive connecting portions 328a and 348a, and conductive connecting portions 328b and 348b) on another side. The first portions are configured to provide one or more electrical terminals for transmitting, through a first path, electrical power for the power supply circuit formed by the circuit assemblies, and the second portions connected to the first portions are configured to provide one or more heat dissipation surfaces to transfer heat from the circuit assemblies through a second path different from the first path. As discussed above, in some embodiments, a circuit assembly may be a full power converter. In some other embodiments, a circuit assembly may include one or more field-effect transistors (FETs). In some other embodiments, a circuit assembly may be one or more portions of the power converter. In some embodiments, the first portions include bottom connecting portion pairs of the frame structures 500a and 500b, and the second portions include top connecting portion pairs of the frame structures 500a and 500b. In some other embodiments, at least one of the first portions and at least one of the second portions may be the same portion.

By performing operations 410-440 discussed above, the semiconductor package 100 shown in FIG. 1A and FIG. 1B can be obtained. As previously discussed, the finalized semiconductor package 100 includes vertically stacked PSiP modules with improved thermal management characteristics and simplified electrical connections. Accordingly, the semiconductor package 100 is suited for various power conversion applications, such as power converter ICs with stacked charge pump circuits.

As shown in the embodiments above, the semiconductor package 100 provides additional interconnections to the PSiP module in the bottom layer (e.g., via conductive connecting portions 350a and 350b). In some other embodiments, one or more additional frames can be provided associated with the two frames shown in the embodiments above, to provide additional interconnects for the PSiP modules in the bottom layer, the intermediate layers, and the top layer.

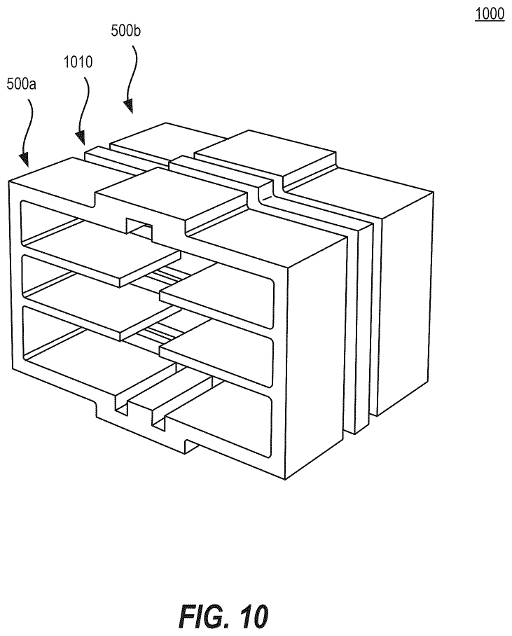

FIG. 10 is a diagram illustrating an exemplary assembly 1000 with an additional frame structure 1010 arranged between the frame structures 500a and 500b shown in FIG. 5A, in accordance with some embodiments of the present disclosure. In some embodiments, the frame structure 1010 may have an identical or similar contour to the frame structures 500a and 500b. In other words, the frame structure 1010, which is disposed between the frame structures 500a and 500b along a longitudinal direction, may also include one or more supporting portions extending substantially vertically, and conductive connecting portions extending substantially horizontally from the one or more supporting portions and defining mounting spaces therebetween. It is noted that in some other embodiments, the frame structure 1010 can also be disposed outside of the frame structures 500a and 500b along the longitudinal direction, and the embodiments illustrated in FIG. 10 is merely an example and not meant to limit the present disclosure.

As shown in FIG. 10, the mounting spaces of the frame structure 1010 align with corresponding ones of the mounting spaces of the frame structures 500a and 500b, as part of the assembly mounting spaces. Accordingly, the power circuit assemblies will be mounted within the assembly mounting spaces defined by the frame structures 500a, 500b, and 1010. For example, each power circuit assembly is further electrically attached to a corresponding one of the conductive connecting portions of the frame structure 1010. Thus, one additional frame structure 1010 provides three additional interconnects for the PSiP module mounted on the bottom layer, and two additional interconnects for each of the PSiP modules mounted on the intermediate layers or the top layer.

In various embodiments, the semiconductor package 100 may also include one or more frame structures 1010 disposed between the frame structures 500a and 500b to provide more interconnects to connect two or more circuit components in different PSiP modules electrically. In some embodiments, the length of the frame structure 1010 along the longitudinal direction may be different from the length of the frame structure 500a or 500b. As shown in FIG. 10, while the frame structures 500a, 500b, and the frame structure 1010 have the same contour, the frame structure 1010 may be slimmer than the frame structures 500a and 500b. Accordingly, the semiconductor package 100 may provide additional interconnects without sacrificing the overall size.

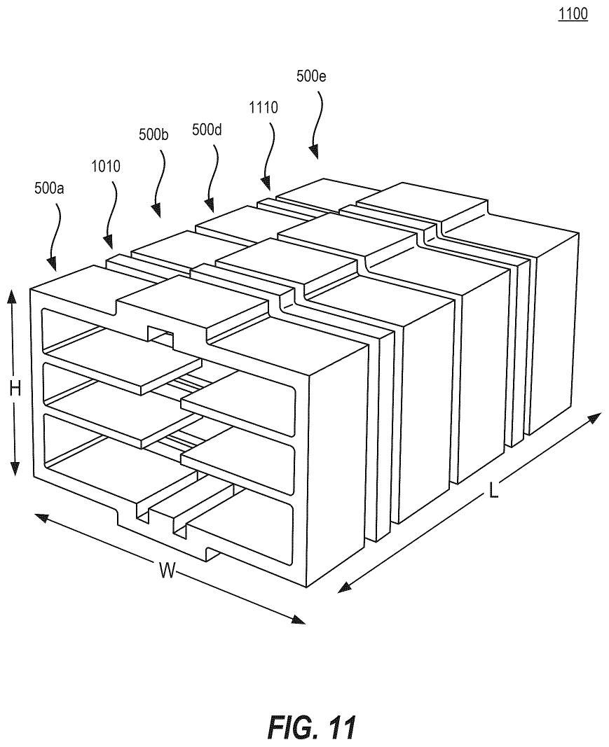

FIG. 11 is a diagram illustrating an exemplary assembly 1100, demonstrating a scaled-up example based on FIG. 10, in accordance with some embodiments of the present disclosure. Compared to the assembly 1000 of FIG. 10, the assembly 1100 further includes frame structures 500d, 500e, and an additional frame structure 1110 arranged between the frame structures 500d and 500e, which collectively provide additional assembly mounting spaces for more power circuit assemblies. Features of the frame structures 500d, 500e, and the additional frame structure 1110 are the same or similar to those of the frame structures 500a, 500b, and 1010 discussed in FIG. 10, and thus are not repeated herein for the sake of brevity.

In the embodiment of FIG. 11, the number of power circuit assemblies in the final package can be doubled by doubling the number of extrusion frames in the assembly 1100. Alternatively stated, by laterally duplicating the assembly 1000 shown in FIG. 10, the number of PSiP modules accommodated in a single package can be scaled up easily based on the practical needs for various power applications. For example, assuming that each PSiP module is able to provide approximately 100W power output with adequate heatsinking, a total of approximately 600W output can be achieved in a final molded package made based on the assembly 1100. In some embodiments, the final molded package may be a package with a length (L) of approximately 16 mm, a width (W) of approximately 12 mm, and a height (H) of approximately 7 mm, but the present disclosure is not limited thereto. It is understood that in different embodiments, the size of the package, the size of a single power circuit assembly, the number of power circuit assemblies and/or frames in the package, the number of stacking layers in the package, the arrangement of conductive pads, the contour of the frames, etc., can be designed or modified according to practical needs. The embodiments disclosed in the present disclosure are simplified examples, and not meant to limit the present disclosure.

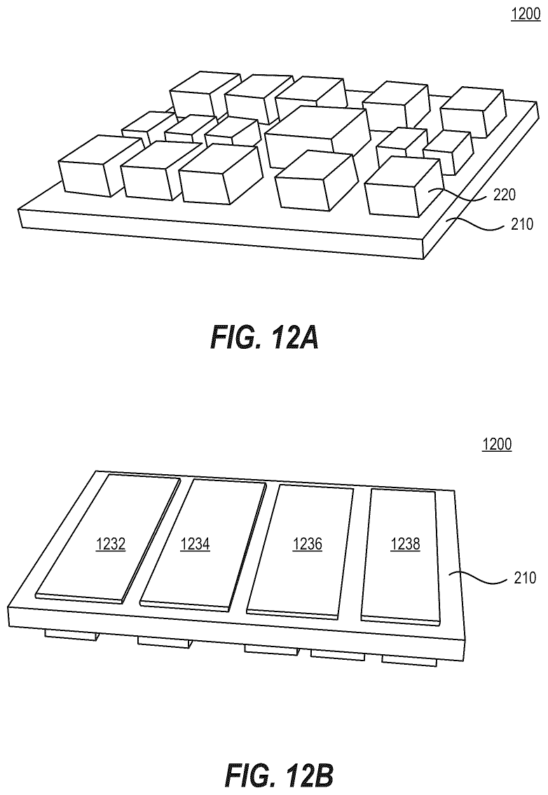

For example, the power circuit assemblies and the frames may be implemented using alternative designs. FIG. 12A and FIG. 12B are respective top and bottom views of another exemplary power circuit assembly 1200, in accordance with some embodiments of the present disclosures. Similar to the power circuit assembly 200 in FIG. 2A and FIG. 2B, in some embodiments, the power circuit assembly 1200 also includes the substrate 210, with one or more passive components 220 mounted on a first side (e.g., a top side) of the substrate 210.

Compared to the power circuit assembly 200 in FIG. 2A and FIG. 2B, the power circuit assembly 1200 provides an alternative layout of the connections on the PSiP module. As shown in FIG. 12B, in the power circuit assembly 1200, four conductive pads 1232, 1234, 1236, 1238 are mounted on a second side (e.g., a bottom side) opposite the first side. Conductive pads 1232-1238 may be electrically coupled to one or more corresponding passive components 220 mounted on the first side via conductive features, such as vias or conductive lines, located on or within the substrate 210. Compared to the conductive pads 232-244 in FIG. 2B, the conductive pads 1232-1238 are arranged differently and aligned in the same row.

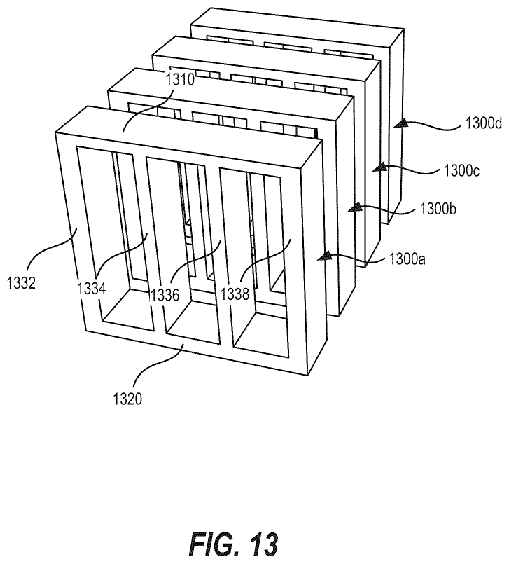

FIG. 13 is a diagram illustrating exemplary frame structures 1300a, 1300b, 1300c, and 1300d for stacking multiple power circuit assemblies 1200 of FIG. 12A and FIG. 12B, in accordance with some embodiments of the present disclosure. In some embodiments, frame structures 1300a, 1300b, 1300c, and 1300d may be copper extrusions or a 3D printed part. Compared to frame structures 500a and 500b in FIG. 5A, frame structures 1300a, 1300b, 1300c, and 1300d eliminate sacrificial connector portions. In each of the frame structures 1300a, 1300b, 1300c, and 1300d, conductive connecting portions 1332, 1334, 1336, and 1338 are located between the supporting portions 1310 and 1320, defining mounting spaces therebetween for mounting the power circuit assemblies. In FIG. 13, the supporting portions 1310, 1320 and the conductive connecting portions 1332, 1334, 1336, and 1338 respectively extend along a first direction (e.g., a horizontal direction) and a second direction (e.g., a vertical direction) substantially perpendicular to the first direction, but the present disclosure is not limited thereto.

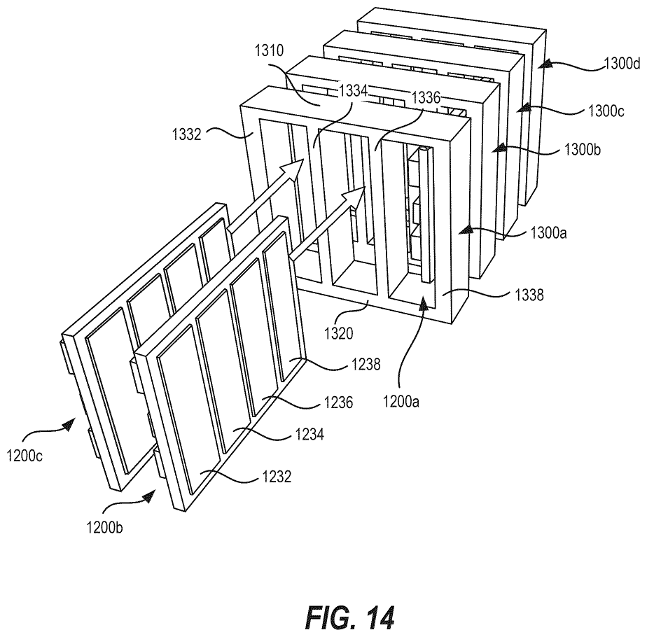

FIG. 14 is a diagram illustrating power circuit assemblies 1200a, 1200b, and 1200c accommodated and stacked in frame structures 1300a-1300d, in accordance with some embodiments of the present disclosure. As shown in FIG. 14, each of the power circuit assemblies 1200a, 1200b, and 1200c can be inserted into a corresponding assembly mounting space, in which the mounting spaces of the frame structures 1300a-1300d are aligned. Then, the assembly shown in FIG. 14 can be passed through an air flow soldering process line to attach the power circuit assemblies 1200a, 1200b, and 1200c to the four frame structures 1300a-1300d. In the embodiment of FIG. 14, the power circuit assemblies 1200a, 1200b, and 1200c (e.g., PSiP modules) may be inserted vertically into multiple frame structures 1300a-1300d.

For each of the power circuit assemblies 1200a, 1200b, and 1200c, four conductive pads 1232, 1234, 1236, and 1238 are coupled and electrically attached respectively to the four frame structures 1300a-1300d separately. For example, conductive pad 1232 of the power circuit assembly 1200a is electrically attached to the conductive connecting portion 1338 of the frame structures 1300a, while corresponding conductive pads 1232 of the power circuit assemblies 1200b and 1200c are respectively electrically attached to conductive connecting portions 1336 and 1334 of the frame structure 1300a. Similarly, conductive pads 1234, 1236, and 1238 of the power circuit assemblies 1200a-1200c are respectively electrically attached to conductive connecting portions of the frame structure 1300b, 1300c, and 1300d. Accordingly, power circuit assemblies 1200a, 1200b, and 1200c can be mounted within assembly mounting spaces defined by the frame structures 1300a-1300d, with the frame structures 1300a-1300d being configured to provide connections, e.g., by extrusions, for signaling between power circuit assemblies 1200a, 1200b, and 1200c. In the embodiments of FIGS. 12A-14, each frame is connected to one common pad (e.g., via one of the conductive pads 1232, 1234, 1236, and 1238) of multiple power circuit assemblies 1200a, 1200b, and 1200c to achieve a parallel connection. Therefore, sacrificial connector portions, which are removed during the grinding process to separate multiple terminals, are not required in the frame structures 1300a-1300d.

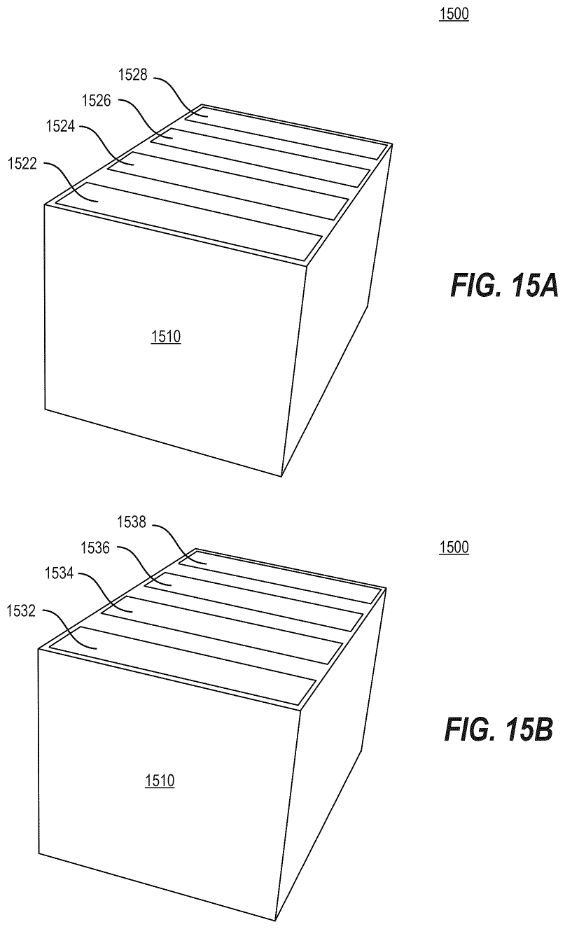

FIG. 15A and FIG. 15B are respective top and bottom views of an exemplary semiconductor package 1500, which can be obtained after applying a molding process and a grinding process to the assembly shown in FIG. 14, in accordance with some embodiments of the present disclosures. As shown in FIG. 15A and FIG. 15B, the semiconductor package 1500 having a molded body 1510 may provide multiple top-side terminals 1522, 1524, 1526, and 1528 at a top surface of the semiconductor package 1500 and multiple bottom-side terminals 1532, 1534, 1536, and 1538 at a bottom surface of the semiconductor package 1500. In FIG. 15A and FIG. 15B, the number of the top-side terminals 1522, 1524, 1526, and 1528 and the number of the bottom-side terminals 1532, 1534, 1536, and 1538 are the same. For example, top-side terminals 1522, 1524, 1526, and 1528 may be the exposed parts of supporting portions 1310 of the four frame structures 1300a-1300d on one side of the 3D package after the grinding process, and bottom-side terminals 1532, 1534, 1536, and 1538 may be the exposed parts of supporting portions 1320 of the four frame structures 1300a-1300d on an opposing side of the 3D package after the grinding process. As shown in FIG. 14 and FIGS. 15A-15B, because the power circuit assemblies 1200a, 1200b, and 1200c are inserted vertically into the frame structures 1300a-1300d to form the semiconductor package 1500, conductive pads 1232, 1234, 1236, and 1238 are electrically attached to corresponding conductive connecting portions extending vertically and substantially perpendicular to the conductive terminals (e.g., top-side terminals 1522, 1524, 1526, and 1528 and bottom-side terminals 1532, 1534, 1536, and 1538) of the 3D package.

Similar to the semiconductor package 100 in FIG. 1A and FIG. 1B, the top-side terminals 1522, 1524, 1526, and 1528 may provide heatsinking functionality for components and devices within the semiconductor package 1500, with thermally conductive frame structures 1300a-1300d (e.g., copper frames) and thermally conductive molding material facilitating the thermal dissipation in the semiconductor package 1500. In some embodiments, the semiconductor package 1500 may provide one or more elongated heatsink fins extending from the top-side terminals 1522, 1524, 1526, and 1528 to further increase the heat transfer area. The bottom-side terminals 1532, 1534, 1536, and 1538 may be configured to provide input terminal(s), output terminals, and/or ground terminal(s), for terminals for the power supply circuit.

In summary, the frame structures and the methods for 3D packaging disclosed in the present disclosure can be applied to manufacture 3D packages with improved heat dissipation properties and simplified routing in the packages. In addition, the 3D packages can be scalable vertically by adding layers in each frame structure, or scalable longitudinally by increasing the number of frame structures included in a single package. The frame structures using copper extrusions are cost-effective and have various mechanical and performance characteristics, such as high structural rigidity and high thermal and electrical conductivity.

In the foregoing specification, embodiments have been described with reference to numerous specific details that can vary from implementation to implementation. Certain adaptations and modifications of the described embodiments can be made. It is also intended that the sequence of steps shown in figures is only for illustrative purposes and is not intended to be limited to any particular sequence of steps. As such, those skilled in the art can appreciate that these steps may be performed in a different order while implementing the same method.

The various example embodiments herein are described in the general context of method steps or processes, which may be implemented in one aspect by a computer program product, embodied in a transitory or a non-transitory computer-readable medium. For example, a non-transitory computer-readable storage medium may store a set of instructions that are executable by one or more processors of a device to cause the device to perform a method for designing a frame structure for stacking circuit assemblies. A computer-readable medium may include removable and nonremovable storage devices including, but not limited to, Read Only Memory (ROM), Random Access Memory (RAM), compact discs (CDs), digital versatile discs (DVD), etc.

It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable sub-combination or as suitable in any other described embodiment of the specification. Certain features described in the context of various embodiments are not to be considered essential features of those embodiments unless the embodiment is inoperative without those elements.

The embodiments may further be described using the following clauses:

1. A three-dimensional (3D) package, comprising:
one or more frames each comprising one or more supporting portions and a plurality of conductive connecting portions extending from the one or more supporting portions and defining assembly mounting spaces therebetween;
a plurality of circuit assemblies each mounted in one of the assembly mounting spaces and electrically attached to corresponding one or more of the conductive connecting portions; and
an encapsulating material to encapsulate at least a part of the one or more frames and the plurality of circuit assemblies.

2. The 3D package of clause 1, wherein each of the circuit assemblies comprises a substrate, one or more passive components mounted on a first side of the substrate, and a plurality of conductive pads mounted on a second side opposite the first side and electrically coupled to the one or more passive components.

3. The 3D package of clause 2, wherein each of the circuit assemblies is electrically attached to corresponding one or more of the conductive connecting portions via the conductive pads of the circuit assembly.

4. The 3D package of clause 1, wherein the one or more frames comprise:
a first frame comprising one or more first supporting portions and a plurality of first conductive connecting portions extending from the one or more first supporting portions and defining first mounting spaces therebetween; and
a second frame, aligned with the first frame, comprising one or more second supporting portions and a plurality of second conductive connecting portions extending from the one or more second supporting portions and defining second mounting spaces therebetween, each of the first mounting spaces being aligned with a corresponding one of the second mounting spaces to define an assembly mounting space;
wherein the first frame comprises two first supporting portions extending substantially along a first direction, and the plurality of first conductive connecting portions extend substantially along a second direction in pairs toward each other from the two first supporting portions, adjacent pairs of the first conductive connecting portions defining the first mounting spaces therebetween.

5. The 3D package of clause 4, wherein one pair of the plurality of first conductive connecting portions is a first top connecting portion pair, and one pair of the plurality of second conductive connecting portions is a second top connecting portion pair, the first top connecting portion pair and the second top connecting portion pair being exposed from the encapsulating material to form a plurality of first conductive terminals on a first side of the 3D package.

6. The 3D package of clause 5, wherein one pair of the plurality of first conductive connecting portions is a first bottom connecting portion pair, and one pair of the plurality of second conductive connecting portions is a second bottom connecting portion pair, the first bottom connecting portion pair and the second bottom connecting portion pair being exposed from the encapsulating material to form a plurality of second conductive terminals on a second side opposite the first side of the 3D package.

7. The 3D package of clause 6, wherein the number of the first conductive terminals is different from the number of the second conductive terminals.

8. The 3D package of clause 1, wherein the one or more frames are thermally and electrically conductive.

9. The 3D package of clause 1, wherein the encapsulating material is thermally conductive.

10. The 3D package of clause 1, wherein the one or more frames comprise:
a first frame comprising one or more first supporting portions and a plurality of first conductive connecting portions extending from the one or more first supporting portions and defining first mounting spaces therebetween;
a second frame, aligned with the first frame, comprising one or more second supporting portions and a plurality of second conductive connecting portions extending from the one or more second supporting portions and defining second mounting spaces therebetween, each of the first mounting spaces being aligned with a corresponding one of the second mounting spaces to define an assembly mounting space; and
a third frame comprising one or more third supporting portions and a plurality of third conductive connecting portions extending from the one or more third supporting portions and defining third mounting spaces therebetween that align with corresponding ones of the first and second mounting spaces as part of the assembly mounting spaces;
wherein each circuit assembly is electrically attached to corresponding one or more of the first conductive connecting portions, corresponding one or more of the second conductive connecting portions, and corresponding one or more of the third conductive connecting portions.

11. The 3D package of clause 10, wherein the third frame is disposed between the first and second frames along a longitudinal direction, a length of the third frame along the longitudinal direction is different from a length of the first frame or the second frame.

12. The 3D package of clause 1, wherein at least one of the one or more frames comprises one or more heatsink fins extending from a top portion of the one or more frames.

13. The 3D package of clause 1, wherein at least one of the one or more frames is an extrusion or a CNC-machined part.

14. The 3D package of clause 1, wherein at least one of the one or more frames is a copper extrusion.

15. The 3D package of clause 1, wherein at least one of the one or more frames is a 3D printed copper frame.

16. A frame structure for stacking a plurality of circuit assemblies, comprising:
two supporting portions extending substantially along a first direction;
a plurality of first conductive connecting portions extending substantially along a second direction from one of the two supporting portions; and
a plurality of second conductive connecting portions extending substantially along the second direction from another one of the two supporting portions, the first conductive connecting portions and the second conductive connecting portions defining mounting spaces therebetween for mounting the plurality of circuit assemblies;
wherein in a first connecting portion pair extending from first ends of the two supporting portions, a corresponding one of the first conductive connecting portions and a corresponding one of the second conductive connecting portions are formed in response to a sacrificial process removing a first connector portion protruding from the frame structure at a first side,
wherein the first conductive connecting portions and the second conductive connecting portions are disposed for electrically attaching to corresponding conductive pads of the plurality of circuit assemblies.

17. The frame structure of clause 16, wherein in a second connecting portion pair extending from second ends of the two supporting portions, a corresponding one of the first conductive connecting portions and a corresponding one of the second conductive connecting portions are formed in response to the sacrificial process removing a second connector portion protruding from the frame structure at a second side opposite the first side.

18. The frame structure of clause 17, further comprising:
one or more third conductive connecting portions disposed between the first conductive connecting portion and the second conductive connecting portion of the second connecting portion pair.

19. The frame structure of clause 16, wherein corresponding ones of the first conductive connecting portions and the second conductive connecting portions are horizontally aligned and extend in pairs toward each other.

20. The frame structure of clause 16, wherein the frame structure is thermally and electrically conductive.

21. The frame structure of clause 16, further comprising:
one or more heatsink fins extending from a top portion of the frame structure.

22. The frame structure of clause 16, wherein the frame structure is an extrusion or a CNC-machined part.

23. The frame structure of clause 16, wherein the frame structure is a copper extrusion.

24. The frame structure of clause 16, wherein the frame structure is a 3D printed copper frame.

25. A method for three-dimensional (3D) packaging, comprising:
mounting a plurality of circuit assemblies within assembly mounting spaces defined by a first frame and a second frame aligned with the first frame, the first frame comprising one or more first supporting portions and a plurality of first conductive connecting portions extending from the one or more first supporting portions and defining first mounting spaces, the second frame comprising one or more second supporting portions and a plurality of second conductive connecting portions extending from the one or more second supporting portions and defining second mounting spaces, the first mounting spaces aligned with the second mounting spaces to form the assembly mounting spaces; and
applying an over-molding to obtain a molded package encapsulating the circuit assemblies, the first frame, and the second frame.

26. The method of clause 25, wherein the mounting the plurality of circuit assemblies comprises:
electrically attaching conductive pads of each of the circuit assemblies respectively to corresponding one or more first conductive connecting portions and corresponding one or more second conductive connecting portions.

27. The method of clause 25, wherein a third frame is disposed between the first frame and the second frame, the third frame comprising one or more third supporting portions and a plurality of third conductive connecting portions extending from the one or more third supporting portions and defining third mounting spaces therebetween that align with corresponding ones of the first and second mounting spaces as part of the assembly mounting spaces, the mounting of the plurality of circuit assemblies further comprising:
mounting the plurality of circuit assemblies within the assembly mounting spaces defined by the first frame, the second frame, and the third frame.

28. The method of clause 27, wherein the mounting the plurality of circuit assemblies further comprises:
electrically attaching one or more conductive pads of each of the circuit assemblies respectively to corresponding one or more third conductive connecting portions.

29. The method of clause 25, further comprising:
removing an upper portion and a lower portion of the molded package to expose a plurality of first conductive terminals on a first side of the molded package and a plurality of second conductive terminals on a second side of the molded package, the removing the upper portion and the lower portion of the molded package comprising:
grinding the molded package to remove one or more sacrificial connector portions protruding from the first frame or the second frame.

30. The method of clause 25, wherein the applying the over-molding comprises:
applying a transfer molding with a thermally conductive material filling cavities within the first frame and the second frame.

31. The method of clause 25, further comprising:
forming at least one of the first frame or the second frame by an extrusion process or a CNC-machining process.

32. The method of clause 25, further comprising:
forming at least one of the first frame or the second frame by 3D printing.

33. A three-dimensional (3D) package, comprising:
a plurality of frames aligned with each other, any of the frames comprising two supporting portions extending substantially along a first direction and a plurality of conductive connecting portions defining a plurality of mounting spaces, corresponding mounting spaces of the frames are aligned with each other to define an assembly mounting space; and
a plurality of circuit assemblies each mounted in one of the assembly mounting spaces and each electrically attached to corresponding conductive connecting portions extending along a second direction substantially perpendicular to conductive terminals of the 3D package.

34. The 3D package of clause 33, further comprising:
an encapsulating material to encapsulate at least a part of the plurality of frames and the plurality of circuit assemblies.

35. The 3D package of clause 34, wherein the two supporting portions includes a first supporting portion and a second supporting portion, and the first supporting portions of the frames are exposed from the encapsulating material to form a plurality of first conductive terminals on a first side of the 3D package.

36. The 3D package of clause 35, wherein the second supporting portions of the frames are exposed from the encapsulating material to form a plurality of second conductive terminals on a second side opposite the first side of the 3D package.

37. The 3D package of clause 36, wherein the number of the first conductive terminals and the number of the second conductive terminals are the same.

38. The 3D package of clause 34, wherein the encapsulating material is thermally conductive.

39. The 3D package of clause 33, wherein each of the circuit assemblies comprises a substrate, one or more passive components mounted on a first side of the substrate, and a plurality of conductive pads mounted on a second side opposite the first side and electrically coupled to the one or more passive components.

40. The 3D package of clause 39, wherein each of the circuit assemblies is electrically attached to corresponding conductive connecting portions of the frames via the conductive pads of the circuit assembly.

41. The 3D package of clause 33, wherein the frames are thermally and electrically conductive.

42. The 3D package of clause 33, wherein the plurality of frames are extrusions or machined parts.

43. The 3D package of clause 33, wherein the plurality of frames are copper extrusions or machined parts.

44. The 3D package of clause 33, wherein the plurality of frames are 3D printed copper frames.

45. A non-transitory computer-readable storage medium storing a set of instructions that are executable by one or more processors of a device to cause the device to perform a method for designing a frame structure for stacking a plurality of circuit assemblies, the method comprising:
providing two supporting portions extending substantially along a first direction;
providing a plurality of first conductive connecting portions extending substantially along a second direction from one of the two supporting portions;
providing of second conductive connecting portions extending substantially along the second direction from another one of the two supporting portions, the first conductive connecting portions and the second conductive connecting portions defining mounting spaces therebetween for mounting the plurality of circuit assemblies; and
providing a first connector portion protruding from the frame structure at a first side, wherein the first connector portion is associated with a corresponding one of the first conductive connecting portions and a corresponding one of the second conductive connecting portions in a first connecting portion pair extending from first ends of the two supporting portions, and to be removed during a sacrificial process;
wherein the first conductive connecting portions and the second conductive connecting portions are disposed for electrically attaching to corresponding conductive pads of the plurality of circuit assemblies.

46. The non-transitory computer-readable storage medium of clause 45, wherein the method further comprises:
providing a second connector portion protruding from the frame structure at a second side opposite the first side, wherein the second connector portion is associated with a corresponding one of the first conductive connecting portions and a corresponding one of the second conductive connecting portions in a second connecting portion pair extending from second ends of the two supporting portions, and to be removed during the sacrificial process.

47. The non-transitory computer-readable storage medium of clause 46, wherein the method further comprises:
providing one or more third conductive connecting portions disposed between the first conductive connecting portion and the second conductive connecting portion of the second connecting portion pair.

48. The non-transitory computer-readable storage medium of clause 45, wherein the method further comprises:
horizontally aligning corresponding ones of the first conductive connecting portions and the second conductive connecting portions extending in pairs toward each other.

49. The non-transitory computer-readable storage medium of clause 45, wherein the method further comprises:
providing one or more heatsink fins extending from a top portion of the frame structure.

50. A frame structure for stacking a plurality of circuit assemblies, comprising:
one or more first portions configured to provide one or more electrical terminals for transmitting, through a first path, electrical power for a power supply circuit formed by the plurality of circuit assemblies; and
one or more second portions configured to provide one or more heat dissipation surfaces to transfer heat from the plurality of circuit assemblies through a second path different from the first path.

51. The frame structure of clause 50, further comprising:
one or more supporting portions extending substantially vertically and connecting the one or more first portions and the one or more second portions extending substantially horizontally from the one or more supporting portions.

52. The frame structure of clause 50, wherein the one or more first portions comprise a bottom connecting portion pair of the frame structure, and the one or more second portions comprise a top connecting portion pair of the frame structure.

53. The frame structure of clause 50, wherein the one or more electrical terminals for transmitting the electrical power for the power supply circuit include one or more of an input terminal, an output terminal, and a ground terminal of the power supply circuit.

54. The frame structure of clause 50, wherein the frame structure is thermally and electrically conductive.

55. The frame structure of clause 50, further comprising:
one or more heatsink fins extending from the one or more second portions.

56. The frame structure of clause 50, wherein the frame structure is an extrusion or a CNC-machined part.

57. The frame structure of clause 50, wherein the frame structure is a copper extrusion.

58. The frame structure of clause 50, wherein the frame structure is a 3D printed copper frame.

59. The frame structure of clause 50, wherein at least one of the one or more first portions and at least one of the one or more second portions are the same portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A three-dimensional (3D) package, comprising:
one or more frames each comprising one or more supporting portions and a plurality of conductive connecting portions extending from the one or more supporting portions and defining assembly mounting spaces therebetween;
a plurality of circuit assemblies each mounted in one of the assembly mounting spaces and electrically attached to corresponding one or more of the conductive connecting portions; and
an encapsulating material to encapsulate at least a part of the one or more frames and the plurality of circuit assemblies.
